(19) United States
(12) Patent Application Publication
(10) Pub. No.: US 2025/0316525 A1
(43) Pub. Date: Oct. 9, 2025

(54) Semiconductor Processing System with Horizontal Scan

(71) Applicant: Applied Materials, Inc., Santa Clara, CA (US)

(72) Inventor: Nagendra Madiwal, Gloucester, MA (US)

(21) Appl. No.: 18/626,895

(22) Filed: Apr. 4, 2024

(51) Int. Cl. H01L 21/687; H01J 37/18; H01J 37/20; H01J 37/317; H01L 21/67

(52) U.S. Cl. CPC H01L 21/68764; H01J 37/18; H01J 37/20; H01L 21/67167; H01L 21/67213; H01L 21/68707; H01J 37/3171; H01J 2237/184; H01J 2237/20221; H01J 2237/20278

(57) ABSTRACT

A process chamber that includes an ion source that directs the ion beam downward is disclosed. The platen is disposed on a movable platen assembly within an enclosure. The movable platen assembly moves horizontally to allow the ion beam to process a workpiece disposed on the platen. The process chamber includes tracks disposed on the bottom surface of the enclosure. The movable platen assembly and the tracks serve as a linear motor, which allows the movable platen assembly to move while levitating. A cluster tool that utilizes a plurality of these process chambers is also disclosed. The cluster tool also includes a front-end system and a distribution hub, wherein a central distribution robot transfers workpieces between a load lock and a platen in one of the process chambers.

### FIELD

Embodiments of the present disclosure relate to a semiconductor processing system that includes a horizontal scan mechanism, and more particularly a horizontal scan utilizing magnetic levitation.

### BACKGROUND

Semiconductor workpieces, such as silicon wafers, silicon oxide wafers, gallium nitride wafers and others, may be implanted with impurities to create semiconductor devices, such as transistors. In operation, an ion source is used to generate an ion beam. In some embodiments, a cluster tool may be used, where workpieces enter the cluster tool and are distributed among a plurality of process chambers for processing. The cluster tool may include an atmospheric robot that accepts workpieces from one or more FOUPs (Front Opening Universal Pods) and places them in a load lock. The cluster tool also includes a central distribution robot, located within the vacuum chamber, which removes the workpiece from the load lock and distributes it to one of the process chambers.

In some embodiments, the process chamber may include a platen that is rotatable between a horizontal orientation, which allows workpieces to be loaded onto the platen and a vertical orientation, which allows the workpiece to be processed. Further, the platen may be disposed on the end of a movable shaft, which allows relative movement between the platen and the incoming ion beam in the vertical direction. In some systems, the shaft extends outside the process chamber, such as through use of an air bearing. Further, because of the height used for the vertical scan, the platen may be located at a different elevation than the central distribution robot. Thus, in some systems, each process chamber also includes a dedicated robot that is used to transfer the workpiece from the location where it is placed by the central distribution robot, to the platen. Furthermore, in some systems, the location where the central distribution robot places the workpiece within the process chamber may be an orienter, which is used to establish a known orientation of the workpiece.

Thus, in this configuration, the cluster tool includes one atmospheric robot, one central distribution robot, N process chambers, wherein N may typically be between 1 and 6, each process chamber having an orienter, a dedicated robot, a movable shaft with an air bearing and a rotatable platen.

Consequently, it would be beneficial if there was a cluster tool and a process chamber with a reduced number of complex components. Such a cluster tool may be less expensive and also occupy less space.

### SUMMARY

A process chamber that includes an ion source that directs the ion beam downward is disclosed. The platen is disposed on a movable platen assembly within an enclosure. The movable platen assembly moves horizontally to allow the ion beam to process a workpiece disposed on the platen. The process chamber includes tracks disposed on the bottom surface of the enclosure. The movable platen assembly and the tracks serve as a linear motor, which allows the movable platen assembly to move while levitating. A cluster tool that utilizes a plurality of these process chambers is also disclosed. The cluster tool also includes a front-end system and a distribution hub, wherein a central distribution robot transfers workpieces between a load lock and a platen in one of the process chambers.

According to one embodiment, a process chamber is disclosed. The process chamber comprises an ion source, configured such that an ion beam extracted from the ion source is directed downward; and a movable platen assembly disposed within an enclosure, the movable platen assembly comprising a platen; wherein the movable platen assembly moves horizontally within the enclosure. In some embodiments, the process chamber comprises a linear motor to move the movable platen assembly horizontally. In certain embodiments, the linear motor causes the movable platen assembly to levitate while moving. In certain embodiments, a primary of the linear motor is configured as a track disposed on a bottom surface of the enclosure. In certain embodiments, the movable platen assembly comprises one or more magnets disposed in the movable platen assembly above the primary to form a secondary of the linear motor. In some embodiments, a primary of the linear motor is disposed in the movable platen assembly and a secondary of the linear motor is configured as a track disposed on a bottom surface of the enclosure. In some embodiments, the platen is configured to move in a vertical direction to vary a gap between the platen and the ion source. In some embodiments, the ion source is rotatably mounted to a top surface of the enclosure, so as to allow access to an interior of the enclosure for maintenance.

According to another embodiment, a cluster tool is disclosed. The cluster tool comprises a front-end system, including an atmospheric robot; a distribution hub including a central distribution robot; a load lock disposed between the front-end system and the distribution hub; and one or more process chambers, each process chamber including an ion source and a movable platen assembly disposed in an enclosure, wherein an ion beam from the ion source is directed downward toward a platen located on the movable platen assembly. In some embodiments, the cluster tool comprises an orienter to orient a workpiece prior to delivery to one of the one or more process chambers. In certain embodiments, the orienter is disposed within the load lock. In certain embodiments, the load lock comprises two or more slots, and the orienter is disposed in one of the two or more slots. In some embodiments, each process chamber comprises a linear motor to move the movable platen assembly horizontally. In certain embodiments, a primary of the linear motor is configured as a track disposed on a bottom surface of the enclosure. In certain embodiments, the movable platen assembly comprises one or more magnets disposed in the movable platen assembly above the primary to form a secondary of the linear motor. In some embodiments, a primary of the linear motor is disposed in the movable platen assembly. In certain embodiments, a secondary of the linear motor is configured as a track disposed on a bottom surface of the enclosure. In some embodiments, each ion source is rotatably mounted to a top surface of a respective enclosure, so as to allow access to an interior of the respective enclosure for maintenance. In some embodiments, the central distribution robot is configured to move the workpiece directly from the orienter to the platen in one of the one or more process chambers. In some embodiments, the central distribution robot is configured to move a processed workpiece directly from the platen in one of the one or more process chambers to the load lock.

### BRIEF DESCRIPTION OF THE FIGURES

For a better understanding of the present disclosure, reference is made to the accompanying drawings, which are incorporated herein by reference and in which:

FIG. 1 shows a top view of the cluster tool according to one embodiment;

FIG. 2A shows a side view of the process chamber with the platen in the loading position;

FIG. 2B shows a side view of the process chamber with the platen in the extended position;

FIG. 3 shows a cross-sectional view of the process chamber of FIG. 2A;

FIG. 4A shows an end view of the process chamber;

FIG. 4B shows an expanded view of the movable platen assembly according to one embodiment;

FIG. 4C shows an expanded view of the movable platen assembly according to another embodiment; and

FIG. 5 shows the process chamber opened to allow maintenance.

### DETAILED DESCRIPTION

As described above, cluster tools that are used for semiconductor processing may have many components. It would be desirable to create a new cluster tool that utilized fewer components and occupied less space.

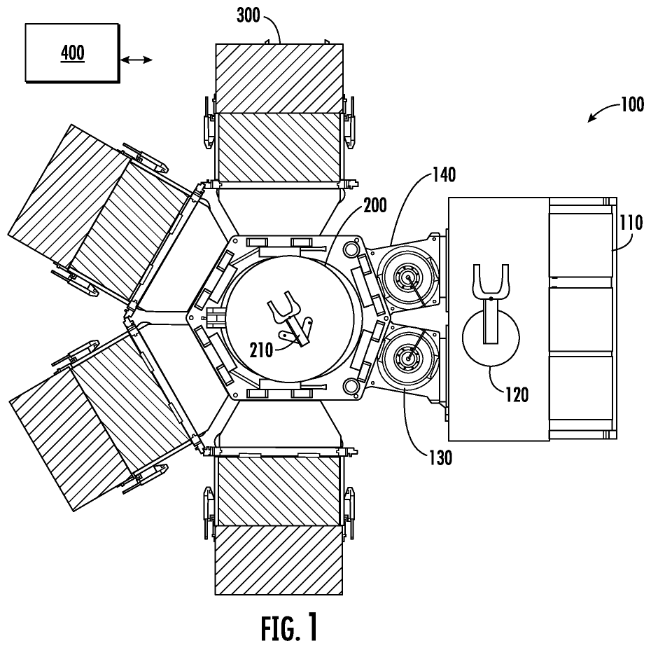

FIG. 1 shows a cluster tool that achieves these objectives. The cluster tool 1 includes a front-end system 100, a distribution hub 200, and a plurality of process chambers 300.

The front-end system 100 includes one or more receptacles 110 that each accept a front opening universal pod (FOUP). An atmospheric robot 120 is located within the front-end system 100 and is configured to move workpieces from one of the FOUPs to a load lock 130 and to return processed workpieces from the load lock 130 to the FOUP. The load lock 130 enables communication between the front-end system 100, which is at atmospheric conditions, and the rest of the cluster tool, which is maintained at near vacuum conditions. In this disclosure, “near vacuum conditions” denotes an environment with a pressure of less than 50 milliTorr. The load lock 130 has two doors; a first door in communication with the atmospheric robot, and a second door in communication with the near vacuum conditions. In operation, only one door is opened at a time. The atmospheric robot 120 places a workpiece in the load lock 130. The first door is then closed and the interior of the load lock 130 is pumped down to near vacuum pressure. The second door is then opened. Processed workpieces are moved in the opposite direction. First, the processed workpiece is placed in the load lock 130 through the open second door. The second door is then closed and the interior of the load lock 130 is vented to atmospheric conditions. The first door is then opened.

In some embodiments, there may be a plurality of load locks 130. Further, in some embodiments, each load lock 130 may have one or more slots, wherein each slot is capable of holding one workpiece.

An orienter 140 is also disposed in the cluster tool. The orienter 140 is used to align the workpiece to a known orientation. For example, each workpiece typically has a notch or other indicia. The orienter 140 is used to rotate the workpiece such that the notch is located at a specific position.

In some embodiments, the orienter 140 is located within the load lock 130. For example, the load lock 130 may have two slots, wherein the first slot also includes an orienter 140. In this way, workpieces that enter the cluster tool are placed in the first slot, while processed workpieces are placed in the second slot.

Further, there may be multiple orienters. For example, if there are multiple load locks 130, there may be one orienter 140 in each load lock. If the orienter 140 is separate from the load lock, the number of orienters 140 may be the same or different from the number of load locks 130.

The cluster tool includes a distribution hub 200 that houses a central distribution robot 210. A plurality of process chambers 300 are disposed around that distribution hub 200. The central distribution robot 210 may have one or more arms that allow the central distribution robot 210 to be able to access the load locks 130, the orienters 140, as well as each process chamber 300. In some embodiments, the central distribution robot 210 may be SCARA (Selective Compliance Articulated Robotic Arm) type robots, capable of movement in the height direction, the radial direction and rotation in the yaw direction.

In some embodiments, the central distribution robot 210 may have two arms. In some embodiments, the arms may be able to move independently. In other embodiments, the arms may be linked in one or more directions, such as the rotational direction.

Finally, the cluster tool includes one or more process chambers 300. While FIG. 1 shows four process chambers 300, the disclosure is not limited to the embodiment shown in FIG. 1. There may be more or fewer process chambers 300, which are each in communication with the distribution hub 200. In certain embodiments, the process chambers 300 may be used to perform pattern shaping, which is the precise and unidirectional modification of the dimensions of on-workpiece features to enhanced the performance of extreme ultraviolet (EUV) patterning.

Each process chamber 300 includes an ion source and a movable platen assembly. The ion source is oriented such that the workpiece is processed while in the horizontal orientation. In this way, the platen does not have to rotate between a loading position and a processing position. Further, unlike traditional platens, the platen is moved along the horizontal direction, while the ion beam is directed downward toward the platen. Note that downward refers to the direction of the force of gravity.

A controller 400 may be in communication with the cluster tool. The controller 400 may include a processing unit, such as a microcontroller, a personal computer, a special purpose controller, or another suitable processing unit. The controller 400 may also include a non-transitory storage element, such as a semiconductor memory, a magnetic memory, or another suitable memory. This non-transitory storage element may contain instructions and other data that allows the controller 400 to perform the functions described herein.

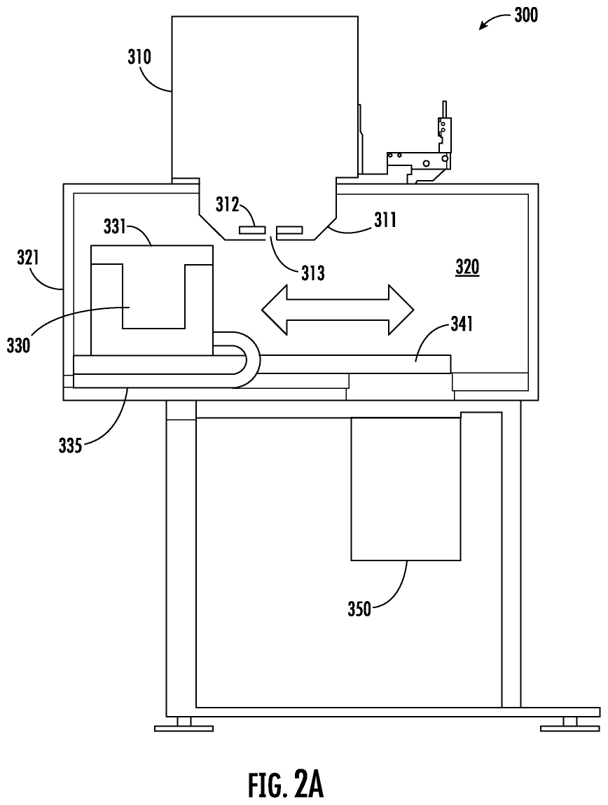

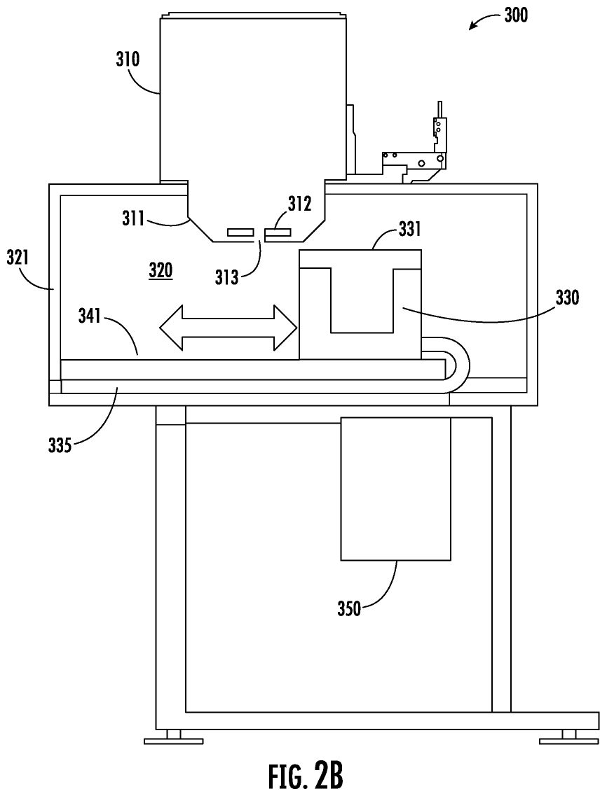

FIGS. 2A-2B show a side view of the process chamber in the loading position and the extended position, respectively. As noted above, the process chamber 300 includes an ion source 310. The ion source 310 may be a capacitively coupled plasma source having a plasma chamber, wherein coils are disposed outside the plasma chamber and are energized to capacitively couple energy into the plasma chamber. The ion source 310 includes a housing 311 that may partially extend into enclosure 320 where the movable platen assembly 330 is located. The housing 311 includes an opening 313 through which ions may pass. Additionally, one or more electrodes 312 may be disposed within the housing 311 to accelerate the ions from the ion source. The one or more electrodes 312 may be biased differently than the plasma within the ion source 310 so as to extract an ion beam from the ion source 310. In certain embodiments, there are no other components disposed between the ion source 310 and the movable platen assembly 330.

The enclosure 320 has two side walls, a top wall, through which the ion source 310 extends, a bottom surface, and two ends. One end of the enclosure 320 of the process chamber includes an access port 321 in communication with the distribution hub 200.

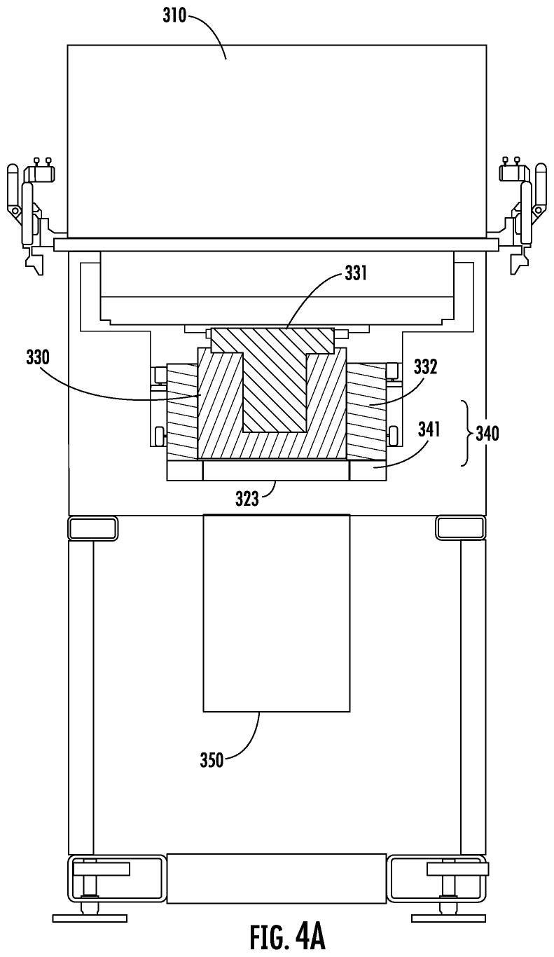

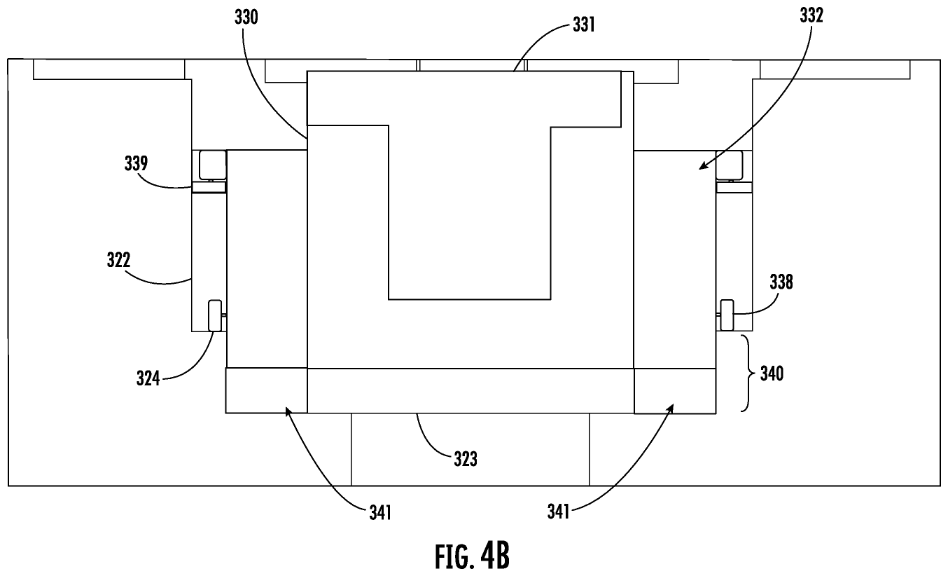

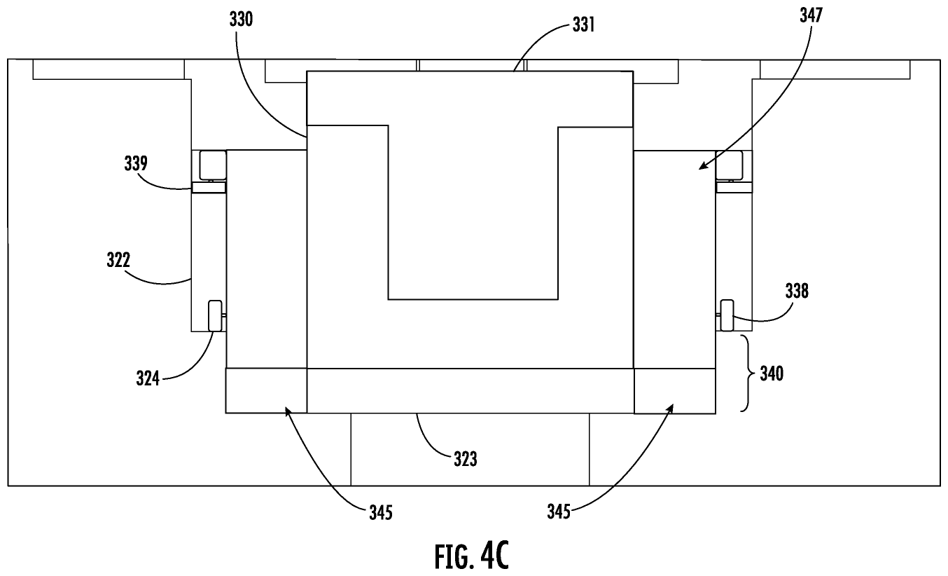

A platen 331, such as an electrostatic platen, rests on the movable platen assembly 330. The movable platen assembly 330 translates horizontally due to linear motors 340. Linear motors 340 (see FIGS. 4A-4C) include a primary (which may be equivalent to the stator of a rotary motor) and a secondary (which may be equivalent to the rotor of the rotary motor). Like rotary motors, linear motors 340 operate through the use of changing magnetic fields within a magnetic field. As the magnetic field on the primary moves, the secondary is moved on it.

In this figure, the direction of travel is left and right. The platen 331 may be in communication with electrical signals, power supplies, and cooling or heating fluids. These connections to the platen 331 may be provided using a conduit 335. The conduit 335 is flexible so as to move as the movable platen assembly 330 moves from the loading position shown in FIG. 2A to the extended position shown in FIG. 2B.

Additionally, a vacuum pump 350 is in communication with the enclosure 320 to maintain the enclosure at the desired pressure.

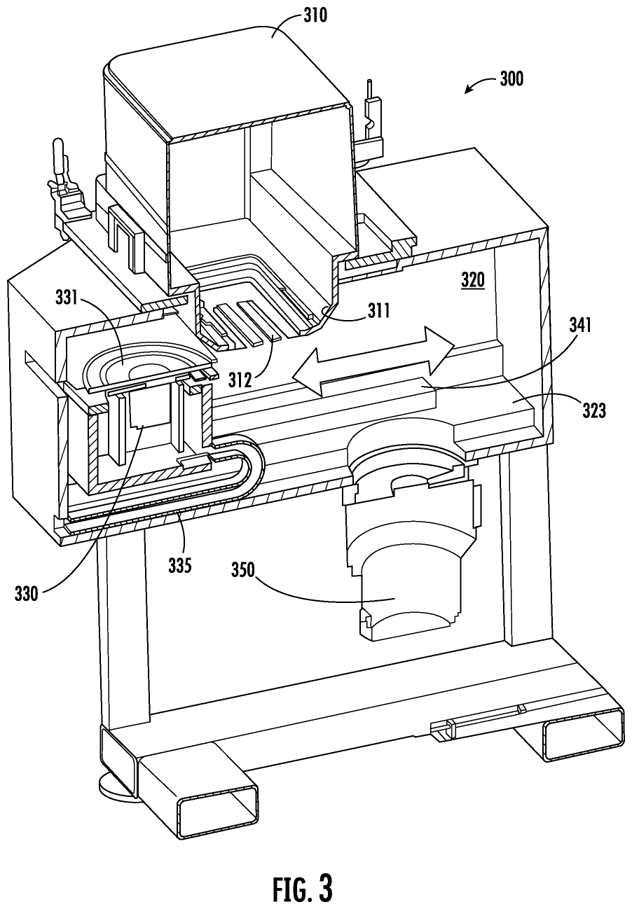

FIG. 3 shows a cross-sectional view of the process chamber 300. Note that, in some embodiments, the primary of the linear motor 340 may be configured as a track 341. The track 341 may be shaped as a rectangular prism, wherein the length of the track may be at least twice the dimension of the workpiece disposed on the platen 331. In certain embodiments, the length of the track may be roughly one meter, although other lengths may be used. The primary of the linear motor 340 may be created using a plurality of overlapping electrical coils, which are energized using two or more different phases of an alternating voltage. In some embodiments, the primary of the linear motor 340 is formed using three different phases of an alternating voltage, each phase separated from the adjacent phase by 120°.

FIG. 4A shows an end view of the process chamber 300. In this view, the direction of travel is perpendicular to the surface of the page. Further, note that in some embodiments, there may be two linear motors 340, each having a primary configured as a track 341 disposed on the bottom surface 323 of the enclosure 320, near opposite side walls of the enclosure 320. These linear motors 340 allow the movable platen assembly 330 to levitate above the linear motors 340. Further, the order in which the phases of the alternating voltage passing through the electrical coils are sequenced determines the direction of the travel.

FIG. 4B shows an enlarged view of the enclosure 320 and the movable platen assembly 330. In some embodiments, one or more magnets 332 are disposed within the movable platen assembly 330 and directly above each of the primaries of the linear motors 340 to form the secondary of the linear motor 340. In some embodiments, the one or more magnets 332 may have a plurality of opposite poles arranged adjacent to one another along the direction of travel. In other embodiments, a conductive material, such as aluminum, may be used rather than magnets 332 to form the secondary of the linear motor 340.

One or more sets of vertical rollers 338 may also be disposed along the sides of the movable platen assembly 330. In addition, the sidewalls of the enclosure 320 may include indentations 322, wherein the width of the enclosure 320 is wider in the middle of the enclosure 320 than at the bottom surface 323. This indentation 322 creates a horizontal ledge 324. In some embodiments, the vertical rollers 338 may be disposed along the side of the movable platen assembly 330 at a height such that the vertical rollers 338 contact the horizontal ledge 324 of the indentation 322 when the movable platen assembly 330 is not levitated. In this way, during assembly, the movable platen assembly 330 may be rolled along the horizontal ledge 324 when installed.

Further, in certain embodiments, there may be horizontal rollers 339 that are used to constrain the movable platen assembly 330 in the direction that is perpendicular to the direction of travel.

While FIGS. 4A-4B describe the tracks 341 as being the primaries while the secondaries are disposed in the movable platen assembly 330, other embodiments are also possible. For example, in the embodiment shown in FIG. 4C, the tracks may serve as the secondary 345 of the linear motor 340. Specifically, a plurality of magnetics may be arranged in the track that forms the secondary 345 of the linear motor 340. In certain embodiments, the plurality of magnets may have opposite poles arranged adjacent to one another along the direction of travel. Further, the primary 347 is disposed within the movable platen assembly 330. As described above, the primary 347 typically comprises a plurality of overlapping electrical coils, which are energized using two or more different phases of an alternating voltage. In some embodiments, the primary 347 of the linear motor 340 is formed using three different phases of an alternating voltage, each phase separated from the adjacent phase by 120°.

Thus, in both embodiments, the linear motor 340 is formed using a primary and a secondary, wherein one of these is disposed within the movable platen assembly 330 and the other is disposed in the track at the bottom surface 323 of the enclosure 320.

Having described the structure of the cluster tool, a description of its operation is provided. First, the atmospheric robot 120 removes an unprocessed workpiece from one of the FOUPs, and places the unprocessed workpiece in one of the load locks 130 through the first door. That first door is then closed and the load lock 130 is pumped down to near vacuum conditions. In some embodiments, the orienter 140 is disposed within the load lock 130, and the unprocessed workpiece is oriented while the load lock 130 is being pumped down. Afterwards, the second door is opened, which exposes the unprocessed workpiece to the distribution hub 200. If the load lock 130 does not include an orienter 140, the central distribution robot 210 then removes the unprocessed workpiece from the load lock 130 and places it on the orienter 140 and waits until the unprocessed workpiece is oriented. It then removes the unprocessed workpiece from the orienter 140 and places it on one of the platens 331 in one of the process chambers 300 through the access port 321. If the orienter 140 is disposed within the load lock 130, the central distribution robot 210 may remove the unprocessed workpiece from the load lock 130 and place it directly on one of the platens 331 in one of the process chambers 300 through the access port 321.

Once the unprocessed workpiece is disposed on the platen 331, it may be processed. In certain embodiments, the platen 331 may be capable of vertical movement, so as to vary the gap between the top surface of the platen 331 and the ion source 310. The gap that is used may vary based on the recipe being used. In certain embodiments, the platen 331 may have a range of motion in the vertical direction of more than 20 mm. In some embodiments, the range of motion may be 30 mm or more.

The ion source 310 is activated and generates an ion beam that is directed downward. Additionally, the linear motor 340 is activated, allowing the movable platen assembly 330 to levitate above the bottom surface 323. The phases of the alternating voltage applied to the linear motor 340 are then sequenced such that the movable platen assembly 330 moves from the loading position, shown in FIG. 2A to the extended position, shown in FIG. 2B. The phases of the alternating voltage applied to the linear motor 340 are then modified such that the movable platen assembly 330 moves from the extended position back to the loading position. This may repeat a plurality of times. Once the workpiece has been processed, the central distribution robot 210 removes the workpiece from the platen 331 through the access port 321 and returns the processed workpiece to the load lock 130 through the second door. The load lock 130 is then vented to atmospheric conditions and the first door is opened. The atmospheric robot 120 then removes the processed workpiece from the load lock 130 and returns it to one of the FOUPs.

This process is then repeated. Note that the atmospheric robot 120 may remove a second unprocessed workpiece from one of the FOUPs before the first workpiece has been returned to the FOUP. The rate at which the workpieces are processed may be determined based on the process time of the process chamber, the speed and number of arms on the central distribution robot 210, the number and speed of the orienters 140 and the number of available slots in the load lock 130.

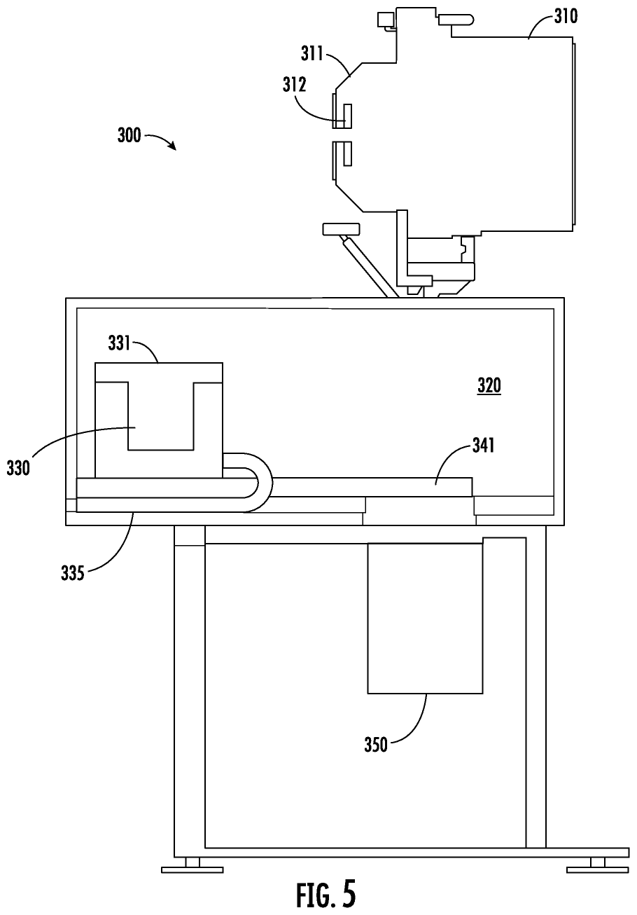

In addition, as shown in FIG. 5, in some embodiments, the ion source 310 may be rotatable so as to allow access to the enclosure 320, such as for preventative maintenance. The top surface of the enclosure 320 may include a sealing material, such that when in the operating position, the ion source 310 is sealed to the top surface. Further, the ion source 310 may be hinged to the top surface along one side.

The system described herein has many advantages. First, the cluster tool may include fewer components. As described above, due to the horizontal scan, air bearings, which may be problematic, may be eliminated. The removal of the air bearing and movable shaft may reduce issues associated with deposits forming on the movable shaft and entering the air bearing. Additionally, the current vertical scan approach utilizes a process chamber that is at a different height than the distribution hub, such that dedicated robots are used within each process chamber 300. However, in the presently disclosed system, there is no dedicated robot for each process chamber 300. Rather, the central distribution robot 210 may be used to place and remove workpieces directly from the platens 331. Because of these improvements, the overall size of the cluster tool may be smaller than is otherwise possible. In some embodiments, the area used by the presently disclosed cluster tool may be less than 75% of the area currently used for a cluster tool. Further, in certain embodiments, the area used by the presently disclosed cluster tool may be about 50% of the area currently used for a cluster tool.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A process chamber, comprising:
an ion source, configured such that an ion beam extracted from the ion source is directed downward; and
a movable platen assembly disposed within an enclosure, the movable platen assembly comprising a platen; and
wherein the movable platen assembly moves horizontally within the enclosure.

2. The process chamber of claim 1, further comprising a linear motor to move the movable platen assembly horizontally.

3. The process chamber of claim 2, wherein the linear motor causes the movable platen assembly to levitate while moving.

4. The process chamber of claim 2, wherein a primary of the linear motor is configured as a track disposed on a bottom surface of the enclosure.

5. The process chamber of claim 4, wherein the movable platen assembly comprises one or more magnets disposed in the movable platen assembly above the primary to form a secondary of the linear motor.

6. The process chamber of claim 2, wherein a primary of the linear motor is disposed in the movable platen assembly and a secondary of the linear motor is configured as a track disposed on a bottom surface of the enclosure.

7. The process chamber of claim 1, wherein the platen is configured to move in a vertical direction to vary a gap between the platen and the ion source.

8. The process chamber of claim 1, wherein the ion source is rotatably mounted to a top surface of the enclosure, so as to allow access to an interior of the enclosure for maintenance.

9. A cluster tool, comprising:
a front-end system, including an atmospheric robot;
a distribution hub including a central distribution robot;
a load lock disposed between the front-end system and the distribution hub; and
one or more process chambers, each process chamber including an ion source and a movable platen assembly disposed in an enclosure, wherein an ion beam from the ion source is directed downward toward a platen located on the movable platen assembly.

10. The cluster tool of claim 9, further comprising an orienter to orient a workpiece prior to delivery to one of the one or more process chambers.

11. The cluster tool of claim 10, wherein the orienter disposed within the load lock.

12. The cluster tool of claim 10, wherein the load lock comprises two or more slots, and the orienter is disposed in one of the two or more slots.

13. The cluster tool of claim 9, wherein each process chamber comprises a linear motor to move the movable platen assembly horizontally.

14. The cluster tool of claim 13, wherein a primary of the linear motor is configured as a track disposed on a bottom surface of the enclosure.

15. The cluster tool of claim 14, wherein the movable platen assembly comprises one or more magnets disposed in the movable platen assembly above the primary to form a secondary of the linear motor.

16. The cluster tool of claim 13, wherein a primary of the linear motor is disposed in the movable platen assembly.

17. The cluster tool of claim 16, wherein a secondary of the linear motor is configured as a track disposed on a bottom surface of the enclosure.

18. The cluster tool of claim 9, wherein each ion source is rotatably mounted to a top surface of a respective enclosure, so as to allow access to an interior of the respective enclosure for maintenance.

19. The cluster tool of claim 10, wherein the central distribution robot is configured to move the workpiece directly from the orienter to the platen in one of the one or more process chambers.

20. The cluster tool of claim 9, wherein the central distribution robot is configured to move a processed workpiece directly from the platen in one of the one or more process chambers to the load lock.
